(19) United States
(12) Patent Application Publication
(10) Pub. No.: US 2007/0128528 A1
(43) Pub. Date: Jun. 7, 2007

(54) Mask blank and photomask having antireflective properties

(76) Inventors: Gunter Hess, Meiningen (DE); Hans Becker, Frankfurt (DE); Oliver Goetzberger, Meiningen (DE); Markus Renno, Meiningen (DE); Ute Buttgereit, Zella-Mehlis (DE); Frank Schmidt, Jena (DE); Frank Sobel, La Baule (CA)

Correspondence Address: MILLEN, WHITE, ZELANO & BRANIGAN, P.C., 2200 CLARENDON BLVD., SUITE 1400, ARLINGTON, VA, 22201, US

(21) Appl. No.: 11/526,866

(22) Filed: Sep. 26, 2006

Related U.S. Application Data
(60) Provisional application No. 60/720,453, filed on Sep. 27, 2005.

(51) Int. Cl. G21K 5/00; G03F 1/00

(52) U.S. Cl. 430/5; 378/35

(57) ABSTRACT

The present invention relates to mask blanks with anti reflective coatings comprising at least two sublayers. Such bilayer or multilayer anti reflective coatings are advantageous for binary and phase shift mask blanks for use in lithography for an exposure wavelength of 300 nm or less with improved anti reflection properties; and to EUVL mask blanks having improved inspection properties.

This application claims the benefit of U.S. Provisional Application Ser. No. 60/720,453, filed Sep. 27, 2005, the entire disclosure of which is hereby incorporated by reference.

### FIELD OF THE INVENTION

The present invention relates to mask blanks with anti reflective coatings comprising at least two sublayers. Such bilayer or multilayer anti reflective coatings are advantageous for binary and phase shift mask blanks for use in lithography for an exposure wavelength of 300 nm or less with improved anti reflection properties; and to EUVL mask blanks having improved inspection properties.

### BACKGROUND OF THE INVENTION

Reflections occur at every interface of a mask and are known as flare. In the stepper, incident light is first reflected at the mask backside and then especially internally at the opaque metallic coating. Multiple reflections inside the substrate may lead to the waveguide effects. Also light reflected back from the wafer can be reflected at the absorber or phase shifter layer. All these reflections have a negative impact on the resist exposure at the wafer level. These flare effects were already observed using 248 nm lithography but could be neglected. For high numerical aperture 193 nm lithography and 65 nm node feature sizes and below flare effects become important and have to be addressed.

It is therefore an object of the present invention to provide novel phase shift mask blanks for exposure wavelengths of 300 nm or less that provide improved anti reflection properties.

Upon further study of the specification and appended claims, further objects and advantages of this invention will become apparent to those skilled in the art.

### SUMMARY OF THE INVENTION

A first aspect of the invention relates to a mask blank comprising a substrate and a thin film system provided on the substrate, wherein said thin film system comprises at least three anti reflective layers wherein each of said antireflective layers comprises at least two sublayers of different composition, said mask blank being able of producing a photomask at an exposure light having a wavelength of 300 nm or less.

A second aspect of the invention relates to mask blank comprising a substrate and a thin film system provided on the substrate, wherein said thin film system comprises at least one anti reflective layer having at least two sublayers wherein said anti reflective layer comprises a sublayer comprising oxides and/or nitrides of B, Al and/or Ga, said mask blank being able of producing a photomask at an exposure light having a wavelength of 300 nm or less.

A third aspect of the invention relates to a substrate for a mask blank said mask blank being able of producing a photomask at an exposure light having a wavelength of 300 nm or less; wherein said substrate comprises an anti reflective layer on the front side and on the backside of the substrate, wherein said anti reflective layers each comprise at least two sublayers of different composition.

A forth aspect of the invention relates to a substrate for a mask blank said mask blank being able of producing a photomask at an exposure light having a wavelength of 300 nm or less; wherein said substrate comprises an anti reflective layer on the front side and/or on the backside of the substrate; wherein said anti reflective layer comprises at least two sublayers of different composition; and wherein at least one sublayer comprises oxides and/or nitrides of B, Al and/or Ga.

A fifth aspect of the invention relates to a mask blank comprising a substrate and a thin film system provided on the substrate, wherein said thin film system comprises an absorbing layer and an anti reflective layer on the absorbing layer, wherein said anti reflective layer on the absorbing layer comprises at least two sublayers of different composition, said mask blank being able of producing a photomask at an exposure light having a wavelength of 300 nm or less.

A sixth aspect of the invention relates to a mask blank comprising a substrate and a thin film system provided on the substrate, wherein said thin film system comprises a functional layer and an anti reflective layer having at least two sublayers under said functional layer, wherein said anti reflective layer can be etched by the same etching agent as said functional layer, wherein the anti reflective layer comprises at least two sublayers of different composition, said mask blank being able of producing a photomask at an exposure light having a wavelength of 300 nm or less.

A seventh aspect of the invention relates to an EUVL mask blank comprising a substrate and a thin film system provided on the substrate; wherein said thin film system comprises
a reflective multilayer stack
an absorber layer
   and wherein on the absorber layer an antireflection layer comprising at least two sublayers is provided, said sublayers comprising a dielectric layer and a semitransparent layer.

### BRIEF DESCRIPTION OF THE DRAWINGS

Various other features and attendant advantages of the present invention will be more fully appreciated as the same becomes better understood when considered in conjunction with the accompanying drawings, in which like reference characters designate the same or similar parts throughout the several views, and wherein:

FIG. 1 shows a schematic cross section of a binary mask blank (FIG. 1a) and a photomask (FIGS. 1b and 1c) according to an embodiment of the invention.

FIG. 2 shows a schematic cross section of an attenuated embedded phase shift mask blank (FIG. 2a), an intermediate product (FIG. 2b) and a photomask (FIG. 2c) according to a further embodiment of the invention.

FIG. 3 shows a schematic cross section of a substrate having anti reflective coatings on the front and back side. Anti reflective coatings 4 and/or 5 may comprise two sublayers (4a, 4b, 5a, 5b).

FIGS. 4 to 6 show further examples of binary mask blanks according to further embodiments of the invention. FIG. 4 shows a binary mask blank comprising an absorbing layer 2 on a substrate 1. On absorbing layer 2 an AR coating is provided. A further AR coating 4 comprising two sublayers (4d, 4c) is provided on the backside of the substrate 1. FIG. 5 shows a binary mask blank comprising AR coatings 8, 6, and 4 on the frontside and backside of the absorbing layer and on the backside of the substrate. FIG. 6 shows a binary mask blank additionally comprising an AR coating on the frontside of the substrate 5. Each of the AR coatings in FIGS. 5 and 6 comprises two sublayers.

FIGS. 7 to 9 show further examples of phase shift mask blanks according to further embodiments of the invention. FIG. 7 shows a phase shift mask blank comprising AR coatings 8, 7, and 4 on the frontside of the absorbing layer 2, on the backside of the phase shift layer 3 and on the backside of the substrate 1. Each of the AR coatings in FIG. 7 comprises two sublayers. FIG. 8 shows a binary mask blank comprising bilayer AR coatings 4 and 5 on the backside and frontside of the substrate 1, a bilayer AR coating 7 on the backside of the phase shift layer and a monolayer AR coating 8 on the front side of the absorbing layer 2. FIG. 9 shows a phase shift mask blank comprising bilayer AR coatings 4 and 5 on the backside of the substrate 1 and on the backside of the phase shift layer and additional single layer AR coatings 8, 9 on the frontside of the phase shift layer 3 and absorbing layer 2.

FIG. 10a shows the dispersion of Al₂O₃ and FIG. 10b shows the dispersion of SiO₂.

FIG. 11 shows a comparison of spectral reflection and transmission curves of a coated substrate according to an example of the invention to an uncoated substrate.

FIG. 12 shows the internal reflectance spectrum of a binary mask blank (FIG. 12a), a phase shift mask blank (FIG. 12b, 12c) and of AR coatings on the front side of the absorber (FIG. 12d) according to specific examples of the invention compared to a standard mask blank without AR coating.

FIG. 13 shows a schematic cross section of an EUV mask blank (FIG. 13a), an intermediate product (FIG. 13b) and an EUV photomask (FIG. 13c) according to an embodiment of the invention.

FIG. 14 compares the reflectivity of an anti reflective coating to be provided on the absorber layer of an EUV mask blank according to one aspect of the invention compared to an anti reflective coating according to the state of the art.

FIG. 15 shows an apparatus for depositing one or more layers of the phase shift mask blank according to an embodiment of the second aspect of the present invention.

These and other objects, features and advantages of the present invention will become apparent upon a consideration of the following detailed description and the invention when read in conjunction with the drawing Figures.

It is to be understood that both the forgoing general description and the following detailed description are merely exemplary of the invention, and are intended to provide an overview or framework for understanding the nature and character of the invention as claimed.

### DETAILED DESCRIPTION OF THE PREFERRED EMBODIMENTS

As known in the art, a “photomask blank” or “mask blank” differs from a “photomask” or “mask” in that the latter term is used to describe a mask blank after it has been structured or patterned or imaged. While every attempt has been made to follow this convention herein, those skilled in the art will appreciate the distinction in not a material aspect of this invention. Accordingly, it is to be understood that the term “photomask blank” or “mask blank” is used herein in the broadest sense to include both imaged and non-imaged photomask blanks.

According to the present invention, the expressions “under” and “on” when used to describe the relative position of a first layer to a second layer in the layer system of the mask blank have the following meaning: “under” means that said first layer is provided closer to the substrate of the mask blank than said second layer and the expression “on” means that said first layer is provided further remote from the substrate than said second layer.

Furthermore, if not explicitly mentioned otherwise, the expressions “under” or “on” can mean “directly under” as well as “under, but at least one further layer is provided in between said two layers” or “directly on” as well as “on, but at least one further layer is provided between said two layers”.

The expression “different etching selectivity” or “different etch chemistry” means that a second layer provided under a first layer is not substantially etched, when the first layer provided on the second layer is etched using a first etching agent. In case the second layer has such a different etching selectivity, a second etching agent will generally be necessary to etch the second layer. The expression “same etching selectivity” means that a second layer provided under a first layer is substantially etched, when the first layer provided on the second layer is etched using a specific etching agent.

If not explicitly mentioned otherwise, the expression “front side of the substrate” means the side of the substrate on which the thin film system is provided, the expression backside of the substrate means the opposite side of the substrate.

According to the present invention, an “anti reflection” or “anti reflective” or “AR” layer or coating reduces the reflection at an adjacent surface. Such anti-reflection layer may be directly adjacent to a surface that is able to reflect light or at least a further layer is provided between the antireflection layer and the reflecting surface.

The invention relates to the application of two or more layered antireflection layers for photomasks for exposure wavelength of in particular less than 200 nm, such as 193 and 157 nm. However, such antireflection layers also have advantages for photomasks for exposure wavelength of from 200 to 300 nm, such as e.g. for 248 nm.

It has been found that anti reflection layers or anti reflective layers each comprising at least two sublayers have particular advantages for advanced mask blanks and photomasks, such as advanced binary, phase shift mask blanks, and even reflective mask blanks for EUVL (extreme UV lithography).

In general, in an anti reflective layer having at least two sublayers, the composition of a sublayer differs from an adjacent sublayer resulting in a difference of optical properties in particular the refractive index from one sublayer to an adjacent sublayer. The composition may differ in view of the elements and/or components contained in the sublayer or may differ in view of the atomic ratios in which elements and/or components are provided in such sublayer. In case a sublayer is positioned adjacent to the substrate, such sublayer will also comprise a different composition as the adjacent substrate.

Preferably, all sub layers of a specific anti reflective layer can be etched using the same etching agent, i.e. in view of the etching procedure, the two or more layered anti reflection layer substantially behaves as a single layer.

Furthermore, all anti reflective layers preferably comprise a sufficient resistance to chemical cleaning agents such as acid and alkaline cleaning agents and have sufficient laser durability.

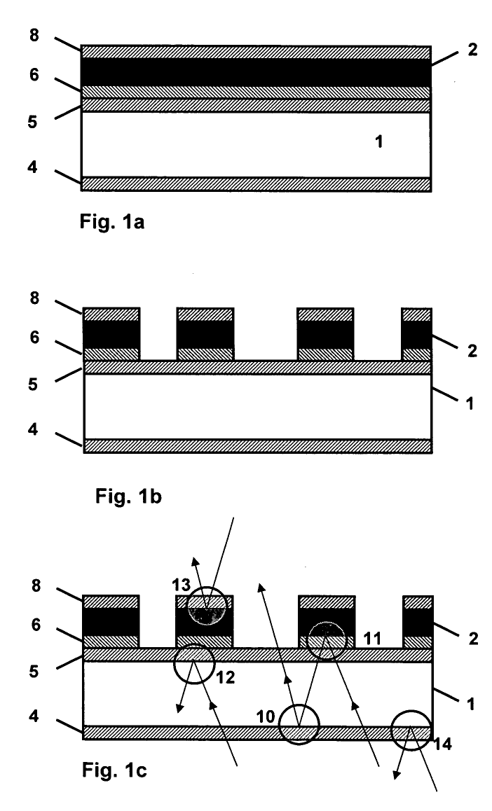

Unwanted reflections are generated at almost any layer interface of the thin film system provided on a mask blank. FIG. 1 schematically shows layer interfaces at which some important reflection occur and where the insertion of an AR layer is advantageous. When during the chip manufacturing process silicon wafers are illuminated through the patterned photo mask, light can be reflected by the backside of a functional layer (11), such as a phase shift or an absorbing layer, by the backside of the substrate (14), or by the frontside surface of the substrate (12). This reflected light can be further reflected by the backside surface of the substrate and produce stray light falling through the recesses of the patterned photo mask. Furthermore, light that is reflected by the wafer surface back to the photo mask can be reflected by the absorbing layer (13) and fall back to the wafer surface. To avoid one or more of such reflections, one or several AR layers may be provided, such as one or more of (4), (5), (6) and (8). If only one AR layer is provided only a portion of the reflection can be avoided. If two or more layers are provided, the total reflection can be reduced to a greater amount. E.g. it was found that the uncoated surface of the synthetic fused silica substrate 1 has a reflection 14 of approximately 4.8% at 193 nm resulting in a significant loss of intensity of the incident light. Typical internal (backside) reflections 11, 12 of a binary chrome or a phase shifting layer system 2 are about 40%. Since these coatings are structured, an ideal AR coating should address reflections at opaque areas and at clear areas. Furthermore, the state of the art absorber 2 has a simple single layer AR coating which was sufficient to reduce reflection 13 to about 12% for lithography wavelengths down to 248 nm. However, such antireflective chrome absorber is not efficient for 193 nm radiation and should furthermore provide optimized reflection also at at least one inspection wavelength.

Mask Blanks having at least Three AR Layers

Thus, a first aspect of the invention relates to mask blank with greatly reduced reflection. Such mask blank comprises a substrate and a thin film system provided on the substrate, wherein said thin film system comprises at least three anti reflective layers wherein each of said antireflective layers comprises at least two sublayers, said mask blank being able of producing a photomask at an exposure light having a wavelength of 300 nm or less, preferably 200 nm or less.

In case mask blank according to this aspect of the invention the invention is a binary mask blank, the thin film system of the binary mask blank comprises at least an absorbing layer. AR layers comprising at least two sublayers can be provided at the following positions:
at the front side of the absorbing layer,
at the backside of the absorbing layer
at the backside of the substrate and/or
at the front side of the substrate.

In case mask blank according to this aspect of the invention the invention is a phase shift mask blank, the thin film system of the phase shift mask blank comprises at least a phase shift layer and an absorbing layer. AR layers comprising at least two sublayers can be provided at the following positions:
at the front side of the absorbing layer,
at the backside of the absorbing layer,
at the front side of the phase shift layer,
at the backside of the phase shift layer,
at the backside of the substrate, and/or
at the front side of the substrate.

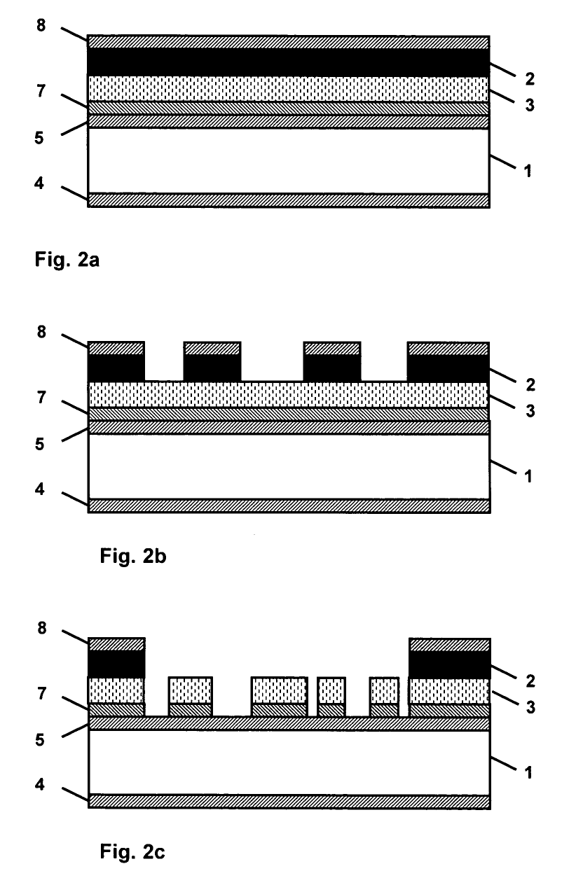

FIGS. 1 and 2 show examples of a binary and a phase shift mask blank with several AR layers. FIG. la shows a binary mask blank having four anti reflective layers; FIG. 2a shows a phase shift mask blank having four anti reflective layers. In FIGS. 1 and 2, anti reflective layers are provided under (4) and on (5) the substrate, under the first functional layer, i.e. under the absorbing layer (6 in FIG. 1a) and under the phase shift layer (6 in FIG. 2a), and on the absorbing layer (8). Each of these AR layers may be a single layered AR layer or an AR layer having at least two layers.

According to this aspect of the invention, at least three AR layers are AR layers comprising at least two sublayers. Besides these three AR layers comprising at least two sublayers, single layered AR may also be provided. E.g. the anti reflective layer at the front side of the absorbing layer may be a single layer antireflective layer or an anti reflective layer comprising at least two sublayers.

According to a preferred embodiment, anti reflective layers comprising at least two sublayers are provided at least at the backside of the substrate and at the back side of the phase shift layer and/or on the front side of the substrate, as shown for a binary mask blank in FIG. 6.

Depending on the position of the anti reflection layer on the mask blank, i.e. in the thin film system or on the substrate, different at least two layered AR layers or specific combinations have particular advantages. In the following, specific AR layers for specific positions in the mask blank are described. An AR coating on the front side of the phase shift layer is preferred if the phase shift layer is a layer having a high transparency.

Essentially Transparent AR Layer

One embodiment relates to at least two layered AR layers wherein both sublayers have a high transparency, i.e. all sublayers are dielectric layers and have an extinction coefficient k of at most 0.1.

Such dielectric sublayers preferably comprise dielectric oxides, oxy nitrides and/or nitrides of Si, Ge, B, Al and/or Ga or mixtures thereof. Each sublayer preferably comprises one of these compounds in an amount of at least 90 at. %, or even of at least 95 at. % and may additionally contain C and/or a metal selected from the group consisting of Ti, Zr, Hf, V, Nb, Ta, Cr, Mo, W, Mn, Fe, Ru, Co, Ni, Cu, Zn, Sn or mixtures thereof, preferably in an amount of at most 10 at. %, preferably at most 5 at. %. According to specific embodiments, this layer essentially consists of oxides and/or nitrides of B, Al and/or Ga. According to one specific embodiment, one or more sublayers essentially consist of oxides, oxy nitrides and/or nitrides of Si, Ge, B, Al and/or Ga or mixtures thereof.

Specific examples of a sublayer having a higher refractive index are layers comprising e.g. Al₂O₃, AlN, AlON, Ga₂O₃, GaN, GaON. Specific examples of a sublayer having a lower refractive index are layers comprising e.g. SiO₂, SiON, B₂O₃, GeO₂.

According to an other embodiment, one or more sublayers of the essentially transparent AR layer comprises a fluoride of a metal selected from the group consisting of Ti, Zr, Hf, V, Nb, Ta, Cr, Mo, W, Mn, Fe, Ru, Co, Ni, Cu, Zn, Sn or mixtures thereof.

Preferably the difference in index of refraction n from one sublayer to an adjacent sublayer and/or to an adjacent layer of the thin film system or the substrate is at least 0.1, more preferably at least 0.15, most preferably at least 0.2.

If the difference in index of refraction of one sublayer to an adjacent sublayer is small, a sufficient anti reflective effect of the layer can be achieved by providing a comparatively thicker layer, i.e. a layer of more than about 40 nm thickness. In case the difference in index refraction is comparatively large the layer thickness can be decreased, i.e. the layer can be comparatively thin, e.g. a layer of about 35 nm or less.

A transparent at least bilayered AR layer is particularly advantageous when provided on one or both sides of the substrate.

Thus, one aspect of the invention relates to an anti reflective layer comprising at least two sublayers can be provided on the front and/or the backside of the substrate.

According to this aspect of the invention, the thickness of the anti reflective layer or layers on the substrate is not critical since these layers are preferably not etched during the patterning process and therefore do not add to the thickness of the part of the thin film system that is etched. Therefore, even comparatively thick sublayers such as sublayers having a thickness of about 40 nm or more can be accepted when necessary due to optical reasons.

Preferably, anti reflective layers comprising at least two sublayers and provided at the front and/or backside of the substrate are substantially not etched when the mask blank is patterned and thus transformed into a photomask. Thus, the anti reflective properties still prevail, after the mask blank has been transformed into a photo mask. Reflections on positions (12) and (10) as shown in FIG. 1c can thus be prevented. On the other side, since all sublayers of the AR layer according to this embodiment are dielectric and transparent, the transparency of the substrate is essentially not impaired by the additional layer.

In case the substrate is a quartz substrate, the uppermost sublayer of the at least two layered AR layer preferably comprises SiO₂ in an amount of at least 95 at. %. Thus, the etching and cleaning behavior of the surface of the substrate is essentially not altered by the provision of an AR layer thereon.

The essentially transparent anti reflective layer or layers on the substrate preferably comprise an even number of sublayers, i.e. an anti reflective layer on the substrate comprises e.g. two, four, six, eight, or even a higher even number of sublayers.

In general, a two layered anti reflection layer on the substrate will be sufficient for design for one wavelength only, e.g. only the lithography wavelength. In such a bilayer system, refractive index of the first sublayer, i.e. the sublayer provided directly on the substrate usually has a higher index of refraction n than the second sublayer, i.e. the sublayer provided on the first sublayer.

In case the anti reflective properties of the substrate have to be adjusted to two wavelengths, an anti reflective layer comprising four sublayers can be provided on the front and/or backside of the substrate. For tuning of the anti reflective properties for a broad band of wavelength, an anti reflective coating having multiple sublayers, e.g. an even number of sublayers of e.g. from 8 to 20 layer, can be provided. In such four or multi sublayer systems, layers of higher refractive index and layers of lower refractive index are provided in an alternating order on the substrate, wherein the first sublayer provided directly on the substrate usually is a sublayer having a higher refractive index.

Preferably, the total reflection of light of the substrate at exposure wavelength of the mask blank or photomask is reduced to at most 1%, more preferably at most 0.5%.

AR Layer on the Absorbing Layer

A further embodiment of the invention relates to mask blanks having an anti reflective layer comprising at least two sublayers on the absorbing layer.

An anti reflective layer on the absorbing layer comprises at least one rather dielectric sublayer and at least one further sublayer having a higher extinction coefficient than said dielectric sublayer. The dielectric sublayer according to this embodiment preferably has an extinction coefficient k of about 0.3 or less, more preferably of about 0.1 or less.

The sequence in which the dielectric sublayer or sublayers and the further sublayer or sublayers are provided on the absorbing layer is not essential. On the absorbing layer a dielectric sublayer can be provided or a further sublayer is provided on the absorbing layer.

The dielectric sublayer preferably comprises an oxide, oxy nitride an/or nitride of a metal selected from the group consisting of Si, Ge, B, Al, Ga, Hf, or mixtures thereof in an amount of preferably at least 90 at. %, more preferably at least 95 at. %; or an oxide of a metal selected from the group consisting of Ti, Zr, V, Nb, Ta, Cr, Mo, W, Mn, Fe, Ru, Co, Ni, Cu, Zn, Sn or thereof mixtures in an amount of preferably at least 90 at. %, more preferably in at least 95 at. %. The dielectric layer may contain other elements, such as O, N, C, or one or m more further metals selected from the groups as mentioned above in an amount of at most 10 at. %, preferably at most 5 at. %. Examples of such dielectric sublayers according to this embodiment of the invention may e.g. be layers comprising B₂O₃, BN, Al₂O₃, Ga₂O₃, SiO₂, SiON, AlN, AlON, HfO, Ta₂O₅, Cr₂O₃, and the like components.

Preferably, each of the further layers comprises an oxide, oxy nitride or nitride of metal selected from the group consisting of Ti, Zr, Hf, V, Nb, Ta, Cr, Mo, W, Mn, Fe, Ru, Co, Ni, Cu, Zn, Sn or mixtures thereof, but has a higher k-value as the dielectric layer as mentioned above.

Preferably, such further layer comprises the same metal as comprised in the absorbing layer and preferably furthermore comprises oxygen, but has a lower k-value as the absorbing layer. E.g., in case the absorbing layer contains Cr, at least one further layer contains CrO, in case the absorbing layer contains CrN, at least one further layer contains CrON, in case the absorbing layer contains TaN, at least one further layer contains TaNO, in case the absorbing layer contains Ta, at least one further layer contains Ta₂O₅.

Preferably, dielectric layer or further layer has the same etch chemistry as the absorbing layer. E.g. in case the absorbing layer can be etched using a chlorine based dry etch process, also the anti reflective layer on the absorbing layer is etched using essentially the same chlorine based dry etch process.

According to a specific embodiment, the top layer or sublayer is a layer chemically resistant to environmental impacts, such as cleaning agents, atmosphere etc. The top layer of the mask blank is exposed to such environmental impacts during the whole life of the mask blank and therefore preferably is stable as described above. Examples of such layers according to specific embodiments are layers essentially consisting of CrO, Ta₂O₅, CrON, TaON, TiO₂, TiON and the like sublayers.

According to an embodiment, the anti reflective layer on the absorbing layer has a thickness of at most 30 nm. According to this embodiment, thinner layers are preferable to reduce the overall thickness of the thin film system, in particular of the part of the thin film system which is structured during the mask making process. A thinner pattern on the mask blank can reduce disturbing three dimensional effects during the lithography process.

Preferably, the total reflection of light of the absorber layer at exposure wavelength of the mask blank or photomask is reduced by the anti reflective coating on the absorbing layer to a reflection of at most 15%, more preferably at most 10% and most preferably at most 1%.

The at least bilayerd AR layer on the absorbing layer may also have a tuning function, i.e. in particular if the AR layer on the absorbing layer consists of three or more sublayers, it is possible to control the reflectivity not only at the illumination wavelength to a value of e.g. 5%, but additionally at two or more inspection wavelengths in a predetermined range. Thus, by an at least bilayered AR layer on the absorbing layer, the total reflection of light of the absorber layer at at least one inspection wavelength, preferably at at least two inspection wavelengths, of the mask blank or photomask has a value of from 5% to 35%, preferably of from 7% to 20%.

A further aspect of the invention related to the above described AR layer on the absorbing layer relates to a mask blank comprising a substrate and a thin film system provided on the substrate, wherein said thin film system comprises an absorbing layer and an anti reflective layer on the absorbing layer, wherein said anti reflective layer on the absorbing layer comprises at least two sublayers, said mask blank being able of producing a photomask at an exposure light having a wavelength of 300 nm or less.

AR Layers at Other Positions such as e.g. Under the Functional Layer

An anti reflective layer comprising at least two sublayers can be provided e.g. on or under a phase shift layer or under the absorbing layer.

The thin film system of a mask blank may comprise further functional layers, such as a barrier layer, i.e. a layer that provides a protection function against environmental effects such as e.g. a cleaning agent to an underlying layer, an inspection control layer, i.e. a layer that provides a controlling function in view of e.g. transmission at one or more inspection wavelengths to the thin film system, an etch stop layer, or the like layers. If necessary, additional AR layers may be provided on or under such further functional layers, wherein such AR layers may be single layered AR layers or layers comprising two or more layers.

An anti reflective layer under a functional layer is advantageous under an absorbing layer in case of a binary mask blank and under phase shift layer in case of a phase shift mask blank, i.e. reduces a substantial portion of the total reflection. In case an anti reflective layer is not provided e.g. under the absorbing layer of a binary mask blank the backside reflection of such the absorbing layer can be as high as about 40% in case of e.g. a chromium layer.

A further advantageous application is an anti reflection layer under a bi or multi layer phase shift layer in particular if the first sublayer is a non- or semi-transparent sublayer having a high k value of 0.8/1.0 or more.

A dielectric sublayer preferably has an extinction coefficient k lower than the extinction coefficient of the semitransparent sublayer. For example, a dielectric sublayer may have an extinction coefficient k of about 0.3 or less, more preferably of about 0.1 or less.

The dielectric sublayer preferably comprises the same elements, components and composition as described for the dielectric sublayer on the absorbing layer.

The semitransparent layer usually has a comparatively low transparency, i.e. a comparatively high extinction coefficient, e.g. an extinction coefficient k of 1 or more. The semitransparent layer preferably is a comparatively thin layer, i.e. a layer having a thickness of less than 10 nm, preferably less than 5 nm.

Preferably, the semitransparent layer comprises a metal or nitride of a metal selected from the group consisting of Ti, Zr, Hf, V, Nb, Ta, Cr, Mo, W, Mn, Fe, Ru, Co, Ni, Cu, Zn, Sn or thereof mixtures, or nitrides or oxy nitrides thereof.

Preferably, the semitransparent sublayer comprises the same element(s) or component(s) as the functional layer.

Preferably, either dielectric sublayer or the semitransparent sublayer have the same etch chemistry as the functional layer, more preferably both sublayers have the same etch chemistry. In case the functional layer comprises two or more sublayers, the anti reflective layer preferably has the same etch chemistry as the sublayer of the functional layer adjacent to the anti reflective layer.

According to an embodiment, the anti reflective layer under a functional layer has an overall thickness of at most 30 nm. According to this embodiment, thinner layers are preferable to reduce the overall thickness of the thin film system, in particular of the part of the thin film system which is structured during the mask making process. A thinner pattern on the mask blank can reduce disturbing three dimensional effects during the lithography process.

Preferably, the total reflection of light of the substrate at exposure wavelength of the mask blank or photomask is at most 10%, more preferably at most 1% and most preferably at most 0.5%.

An aspect of the invention also relates to mask blank comprising a substrate and a thin film system provided on the substrate, wherein said thin film system comprises a functional layer and an anti reflective layer under said functional layer as described above, wherein said anti reflective layer can be etched by the same etching agent as said functional layer, said mask blank being able of producing a photomask at an exposure light having a wavelength of 300 nm or less.

According to one embodiment of this aspect of the invention the mask blank additionally comprising an anti reflective layer, wherein said anti reflective layer is substantially not etched when the functional layer and the anti reflective layer directly the functional layer is etched.

AR Layer Comprising B, Al and/or Ga

One embodiment of the invention relates to at least bi layered anti reflection layers that comprise at least one sub layer comprising oxides, oxy nitrides and/or nitrides of B, Al and/or Ga in an amount of at least 90 at. %, preferably in an amount of at least 95 at. %. According to a specific embodiment, such sub layer essentially consists of one of oxides, oxy nitrides and/or nitrides of B, Al and/or Ga. However, according to other embodiments, the sub layer may further comprise minor amounts of C and/or one or more of a metal selected from the group consisting of Ti, Zr, Hf, V, Nb, Ta, Cr, Mo, W, Mn, Fe, Ru, Co, Ni, Cu, Zn, Sn or mixtures thereof.

Since layers comprising oxides and/or nitrides of B, Al and/or Ga, in particular oxides and/or nitrides of Al, have been found to be advantageous in anti reflective layers for a substrate for a mask blank, a third aspect of the present invention related to a substrate for a mask blank, said mask blank being able of producing a photomask at an exposure light having a wavelength of 300 nm or less; wherein said substrate comprises an anti reflective layer on the front side and/or on the backside of the substrate; wherein said anti reflective layers each comprise at least two sublayers of different composition; and wherein at least one sublayer of at least one anti reflective layer comprises oxides and/or nitrides of B, Al and/or Ga in an amount of at least 90 at. %.

According to a further aspect of the invention, a substrate for a mask blank, in particular a binary mask blank or a phase shift mask blank, is provided, said mask blank being able of producing a photomask at an exposure light having a wavelength of 300 nm or less; wherein said substrate comprises an anti reflective layer on the front side and on the backside of the substrate and wherein said anti reflective layers each comprise at least two sublayers of different composition as described above.

According to a second aspect of the present invention, a mask blank is provided, comprising a substrate and a thin film system provided on the substrate, wherein said thin film system comprises at least one anti reflective layer wherein said anti reflective layer comprises a sublayer comprising oxides and/or nitrides of B, Al and/or Ga, preferably in an amount of at least 90 at. %, more preferably in an amount of at least 95 at. %, said mask blank being able of producing a photomask at an exposure light having a wavelength of 300 nm or less, preferably of 200 nm or less.

An example of a binary mask blank according to the second aspect of the invention comprises a substrate and an absorbing layer; wherein the anti reflective layer comprising a sublayer comprising oxides and/or nitrides of B, Al and/or Ga is provided at the front side of the absorbing layer, at a back side of the absorbing layer, at the front side of the substrate and/or at the backside of the substrate.

An example of a phase shift mask blank according to the second aspect of the invention comprises a substrate, an phase shift layer and a absorbing layer; wherein the anti reflective layer comprising a sublayer comprising oxides and/or nitrides of B, Al and/or Ga is provided at the front side of the absorbing layer, at the back side of the phase shift layer, at the front side of the substrate and/or at the backside of the substrate.

Binary and Phase Shift Mask Blanks

The AR layers according to the invention may be combined with various types of binary and phase shift mask blanks.

A mask blank generally comprises a light absorbing layer or absorbing layer or masking layer or light shielding layer on top of the thin film system. The absorbing layer may comprise at least one metal selected from the group consisting of Ti, Zr, Hf, V, Nb, Ta, Cr, Mo, W, Y, La, Gd and/or nitrides thereof and may contain small amounts such as at most 10 at. % of C, O or mixtures thereof. According to certain embodiments of the present invention, the light absorbing layer comprises at least 80% of Ta, TaN, Cr, CrN or CrON.

A mask blank may additionally comprise further layers such as e.g. one or more of an antistatic layer, an antireflection layer, an etch stop layer, etc.

One or more layers of the mask blank of the present invention may have a gradual change of the composition in different distances from the substrate.

In case a mask blank for an illumination wavelength of 248 nm is provided, the phase shift system preferably has a thickness of at most 250 nm, more preferably of at most 200 nm. In case a mask blank for an illumination wavelength of 193 nm is provided, the phase shift system preferably has a thickness of at most 200 nm, more preferably of at most 160 nm.

A phase shift mask blank usually has a phase shift of substantially 180°. The expression “having a phase shift of substantially 180°” means that the phase shift mask blank provides a phase shift of the incident light sufficient to cancel out light in the boundary section of a structure and thus to increase the contrast at the boundary. According to certain embodiments of the present invention, a phase shift of 160° to 190°, preferably of 170° to 185° is provided.

A phase shift mask blank has a transmission of at least 0.001%, preferably of at least 0.5%, at an exposure light wavelength. Specific examples of preferred transmissions are from about 6% to about 20%, but also high transmission mask blanks of from about 20% to 40% or ultra high transmission mask blanks of up to 95%.

The thin film system of phase shift mask or mask blank of the invention preferably is free from defects having a particle size of 0.5 μm or more. Preferably, said thin film system has at most 50 defects, more preferably at most 20 defects, having a particle size of 0.3 μm to 0.5 μm. With decreasing feature sizes on a photomask, defects having a size of 500 nm or more will pose a problem and therefore must not be present. With respect to defects having a particle size of 0.3 to 0.5 μm, a limited amount of up to 50 defects per mask blank is tolerable for many applications.

Such phase shift mask blank may be an attenuated phase shift mask blank or an alternating mask blank or a mask blank as described in international patent application PCT/EP 2004/00919 and U.S. patent application Ser. No. 10/655,593, the content of which is incorporated herein by reference.

An attenuated phase shift mask blank generally comprises a phase shift system that imposes a phase shift function to the mask blank. Such phase shift system may be a monolayer phase shift system, a bilayer phase shift system or a multiplayer phase shift system. Examples of attenuated phase shift mask blanks employing such mono, bi and multilayer phase shift systems are described in U.S. patent application Ser. No. 10/655,593, EP application number 04 001359, U.S. Pat. No. 5,482,799, U.S. Pat. No. 6,458,496, U.S. Pat. No. 6,274,280, U.S. Pat. No. 5,897,977, U.S. Pat. No. 5,474,864 and U.S. Pat. No. 5,482,799, whereas the content of these documents is incorporated herein by reference.

One embodiment of a bilayer phase shift system comprises a transmission control sublayer and a phase shift control sublayer. The transmission control sublayer preferably also provides an etch stop function. The phase shift control sublayer preferably comprises a material selected from the group consisting of oxides and oxinitrides of Si or Al and mixtures thereof, preferably in an amount of at least 90 at. %, more preferably at least 95 at. %. The phase shift control sublayer may also contain small amounts of C or metals selected from the group consisting of Mg, Y, La, Ti, Zr, Hf, V, Nb, Ta, Cr, Mo, W, Mn, Fe, Co, Ni, Zn, Ge, Sn, Pb and mixtures thereof, in an amount of at most 5 at. %. The phase shift control layer may e.g. comprise SiO₂, SiON, Al₂O₃, AlN, MoSiO, MoSiON, MoSiN or the like components. The transmission control sublayer may be formed of at least one material having a high opacity and preferably comprises a material selected from the group consisting of metals or nitrides of metals of Mg, Si, Y, La, Ti, Zr, Hf, V, Nb, Ta, Cr, Mo, W, Mn, Fe, Co, Ni, Zn, Ge, Sn, Pb, and mixtures of two or more of these metals or nitrides. More preferably the transmission control layer comprises a material selected from the group consisting of Ta, Ti, Zr, Hf, V, Nb, Cr, Mo, and W. In case of a high transmission mask blank, the transmission control sublayer comprises an oxide or oxy nitride of the metals as described above. Examples of bilayered phase shift systems are Ta/Al₂O₃, Ta/SiO₂, Ta/SiON, Ta/AlN, Ta/AlON, Ta/Al₂O₃, Cr/Al₂O₃, Cr/SiO₂, Cr/SiON, Cr/AlN, Cr/AlON, Cr/Al₂O₃, MoSi/SiO₂, MoSi/SiON, MoSi/SiN and the like combinations.

The substrate for a binary or phase shift mask blank as described in this application may be a calcium fluoride substrate, a quartz substrate or a fluorine-doped quartz substrate.

EUV Mask Blank

According to a further aspect of the invention an EUVL mask blank in provided comprising a substrate and a thin film system provided on the substrate;
wherein said thin film system comprises
a reflective multilayer stack
a capping layer
a buffer layer
an absorber layer
   and wherein on the absorber layer an antireflection layer comprising at least two sublayers is provided, said sublayers comprising a dielectric layer and a semitransparent layer.

Masks used in conventional, i.e. non-EUV lithography systems may be inspected by comparing light transmitted in the patterned (or “line”) region of the photomask to the light transmitted in the non-patterned (or “space”) region. The defect detection sensitivity of the inspection system depends on the difference in contrast between light transmitted in the two regions. Conventional transmissive optical masks usually exhibit high inspection contrast since the light will either pass through the mask in the space region or will be blocked by the line region. However, low inspection contrast may present a problem in reflective EUV photomasks. Light absorber materials in the patterned region may typically reflect about 10% to about 45% of incident deep UV (DUV) light used for inspection purposes. The reflector region may typically reflect about 60% of the DUV inspection light. As a result, the signal contrast between the patterned and non-patterned regions may be relatively low.

The absorber layer 22 of the thin film system of the EUV mask blank according to this aspect of the invention comprises a layer of EUV absorbing material, preferably a metal selected from the group consisting of Cr, Ta . . . and/or nitrides thereof and may also contain further elements such as C, B and or Ge. The absorber layer may for example comprise of Cr, Cr+(C, N), TaN and/or TaN+(B, Ge). According to one embodiment of the invention the absorber layer essentially consists of TaN. The absorber layer 12 preferably has a thickness of about 40 to about 70 nm.

On the absorber layer 22 of the EUV mask blank according to this aspect of the invention, an antireflection layer is provided comprising at least two sublayers, said sublayers comprising a dielectric layer and a semitransparent layer. Said antireflection layer of the EUV mask blank according to this aspect of the present invention comprise of material having low reflectivity at non-EUV radiation and serves to improve the reflectivity at inspection wavelengths. Typical inspection wavelengths include, but are not limited to 488 nm, 365 nm, 266 nm, 257 nm, 248 nm, 198 nm and 193 nm. Preferably, the reflection of the absorber layer of the EUV mask blank according to this aspect of the present invention is 15% or less, more preferably 10% or less. According to a specific embodiment, the reflectivity is less than 15%, preferably less than 10%, for at least two inspection wavelengths below 400 nm.

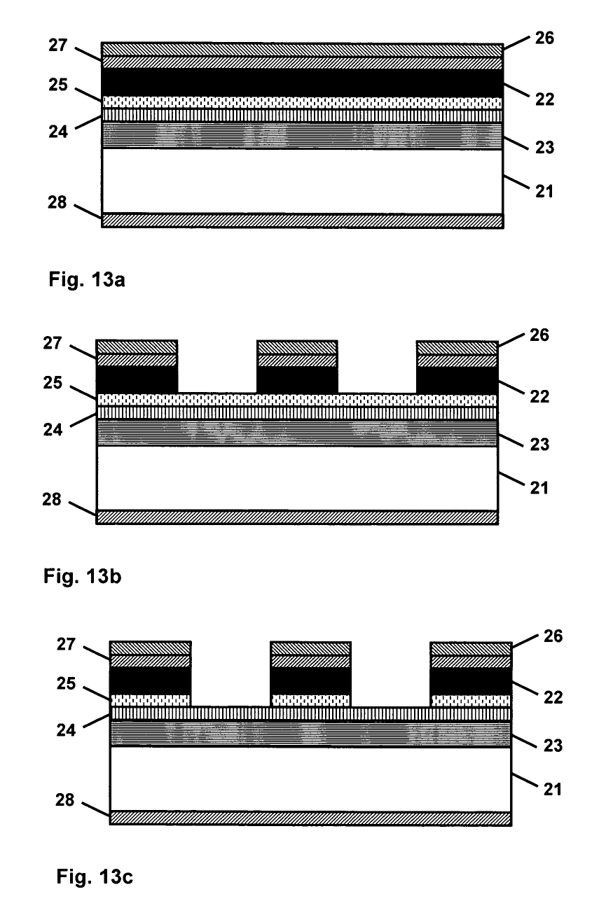

Preferably, in case a bilayer antireflection layer is provided on the absorber layer 22, the dielectric sublayer 27 is provided on the absorber layer and the semitransparent layer 26 is provided on the dielectric sublayer as shown in FIG. 13a.

The dielectric sublayer preferably comprises oxides or oxy nitrides of a metal selected from the group consisting of Si, Al, Ga, B, or mixtures thereof. The dielectric sublayer may for example comprise aluminum oxide, aluminum nitride, aluminum oxy nitride, silicon oxide, silicon nitride or mixtures thereof.

According to a further embodiment the dielectric sublayer further comprises at most 5 at. % of metals selected from the group consisting of Ta, Hf, Sn, Mo, Ti, Fe, Ru, W, Mn, Cu, Cr, Ni, V, Nb, Sn, Co, Zr or mixtures thereof and or C, N or a mixture of thereof.

According to one embodiment of the invention, the dielectric sublayer essentially consists of aluminum oxide Al₂O₃ and/or AlN.

According to a further embodiment, the dielectric sublayer comprises at least 95 at.-% of an oxide of Ta, Hf, Sn, Mo, Ti, Fe, Ru, W, Mn, Cu, Cr, Ni, V, Nb, Sn, Co, Zr or mixtures thereof.

The dielectric layer may serve to improve the tuneability of the system. According to one embodiment of the invention, the layer may be used to optimize the antireflective property of the mask blank at at least two inspection wavelength at one time.

Preferably, the dielectric layer has a thickness of from 2 to 15 nm.

The semitransparent layer preferably comprises a metal selected from the group consisting of Ta, Hf, Sn, Mo, Ti, Fe, Ru, W, Mn, Cu, Cr, Ni, V, Nb, Sn, Co, Zr, or a mixture thereof. The semitransparent layer preferably further comprises N, O, C, B, or mixtures thereof. The semitransparent layer for example may comprise TaON, TaON+(B, Ge), Cr, Cr+(O, N, C).

According to an embodiment, the semitransparent layer essentially consists of TaON.

The semitransparent layer preferably has a thickness of from 2 to 15 nm.

The antireflection layer comprising at least two sublayers preferably has a total thickness of from 10 to 25 nm.

The absorber layer and the antireflection layer have an aggregate thickness preferably of from about 60 nm to about 100 nm. An EUV absorber layer thicker than 100 nm may result in undesirable shadowing problems, while an EUV absorber layer having a thickness of less than 60 nm may be susceptible to inadequate EUV absorption or “leakage” depending upon the materials utilized.

The absorber layer and the antireflection layer preferably have the same etching selectivity, i.e. can be etched using the same etching agent. E.g. when the absorber layer comprises TaN, a chlorine based etching agent may be used, such as e.g. a chlorine based dry etch chemistry using conventional plasma etching techniques, e.g. Cl₂+O₂. Such etching agent is also suitable for etching a TaON semitransparent antireflection sublayer and an Al₂O₃ dielectric antireflection sublayer according to an example of the EUV mask blank according to the present invention.

The EUV mask blank according to this aspect of the invention further comprises a reflective multilayer 23. Such reflective multilayer preferably comprises about 20 to 80, preferably about 40 to 60, pairs of alternating layers of a high index refraction material and a low index refraction material. For example, each high refraction index material may be formed from about 2.8 nm thick molybdenum while each low index refraction material may be formed of from about 4.2 nm thick silicon. The reflective multilayer preferably can achieve about 60 to 75% reflectivity at the peak illumination wavelength.

The EUV mask blank according to this aspect of the invention further may comprise a buffer layer 25. A buffer layer 25 may be positioned between the reflective multilayer 23 and the absorber layer 22 to protect the reflective multilayer 23 during repair procedures. Subsequent to such repair procedures, the buffer layer 25 is etched away in preparation for EUV irradiation of the reflective multilayer. Such a buffer layer preferably comprises materials such as CrN, SiO₂ or SiON and preferably has a thickness of from about 40 to about 60 nm. The buffer layer preferably has an etching selectivity different from the etching selectivity of the absorber layer. In case the absorber layer comprises a material that can be etched with a chlorine based chemistry, the buffer layer preferably is not or not substantially etched with such chlorine based chemistry, but with e.g. a dry etching procedure using a gas that contains fluorine, such as C₄F, C₄F₈, optionally with O₂ gas and/or carrier gas, such as e.g. Ar; or, in particular in case the buffer layer is relatively thin, a wet etching procedure using e.g. an aqueous solution of about 3 to 5% HF.

The EUV mask blank according to this aspect of the invention further may comprise a capping 24 layer provided on the reflective multilayer 23. The capping layer serves to isolate the reflective multilayer from environmental-related degradation processes such as oxidation of molybdenum that may be comprised in the reflective multilayer. The capping layer may e.g. comprise a layer of ruthenium or silicon having a thickness of about 11 nm. The capping layer remains on the reflective multilayer and therefore should preferably have an etching selectivity different from the etching selectivity of the buffer layer.

The EUV mask blank according to this aspect of the invention may further comprise a backside coating of an electrically conducting material such as e.g. chromium.

On the absorber layer (including the antireflection layer of the absorber layer) a (photo)resist layer is coated before structuring of the mask blank to yield a photomask is effected not shown in FIG. 13). The resist layer is structured or patterned using conventional techniques, such as e-beam writing. The resist pattern is transferred into the absorber layer preferably by using plasma etch processes highly selective to the absorber layer as opposed to the underlying buffer layer yielding a patterned intermediate as shown in FIG. 13b. After repair procedures, the buffer layer is removed to yield an EUV photomask as schematically shown in FIG. 13c.

The substrate 21 of the EUV mask blank according to this aspect of the invention preferably comprises a material with a low defect level, good flatness and a smooth surface such as glass or glass ceramic with a low coefficient of thermal expansion (CTE), such as Ti-doped fused silica (e.g. ULE® of Corning) or glass ceramics such as Zerodur® (SCHOTT AG, Germany) or Clear Ceram® (of Ohara Inc., Japan). In certain cases the substrate may be formed from silicon despite the relatively large CTE of silicon, so long as heat can be removed uniformly and effectively during exposure.

Method

Preferably, one or more layers of the thin film system on the mask blank are formed by sputter deposition using a technique selected from the group consisting of dual ion beam sputtering, ion beam assisted deposition, ion beam sputter deposition, RF matching network, DC magnetron, AC magnetron, and RF diode.

According to an embodiment, e.g. a phase shift system and/or optional further layers are deposited in a single chamber of deposition apparatus without interrupting the ultra high vacuum. It is particularly preferred to deposit the silicon and/or aluminum containing layer and the protection layer without interrupting the vacuum. Thus, decontamination of the mask blank with surface defects can be avoided and a mask blank substantially free of defects can be achieved. Such a sputtering technique can e.g. be realized by using a sputter tool that allows sputtering from several targets. Thus, high quality masks having a low defect density and/or highly uniform layers with respect to the thickness of the layers can be achieved.

As the sputtering targets, targets comprising elements or targets comprising components can be used. In case the deposited layer contains an oxide, nitride or oxy nitride of a metal or semimetal, it is possible to use such oxide, nitride or oxy nitride of a metal or semimetal as the target material. However, it is also possible to use a target of a metal or semimetal and to introduce oxygen and/or nitrogen as an active sputtering gas. An active sputtering gas or doping gas reacts with the metal or semimetal or component of the target and/or is incorporated in the deposited layer. In case of the deposition of SiO₂, it is preferred to use a target of Si and to introduce oxygen as an active gas. In case the deposited layer shall comprise nitrogen, it is preferred to introduce nitrogen as a doping gas.

It is also possible to introduce an inactive sputtering gas, i.e. a gas that does not react with the metals of the target and is not deposited in the layer. It is preferred to use inactive gasses such as helium, argon or xenon. Such inactive gasses can be combined with active gasses such as oxygen, nitrogen, nitrogen monoxide, nitrogen dioxide, and dinitrogen oxide or mixtures thereof. Active gasses are gasses that may react with sputtered ions and thus become part of the deposited layer.

Etch Process

As an etching process, a dry etching method using a chlorine-based gas such as Cl₂, Cl₂+O₂, CCl₄, CH₂Cl₂, or a wet etching using acid, alkali or the like may be used. However, a dry etching method is preferred. Also possible are etching methods using a fluorine containing component, reactive ion etching (RIE) using fluorine gasses such as CHF₃, CF₄, SF₆, C₂F₆ and mixtures thereof is preferred. In general, at least two different etching methods and/or agents are employed when etching the mask blanks of the present invention.

The entire disclosures of all applications, patents and publications, cited above and below, are hereby incorporated by reference.

### EXAMPLES

In the following, the design and fabrication of mask blanks according to a preferred embodiment of the present invention are described.

All layers were deposited using a dual ion beam-sputtering tool as schematically shown in FIG. 15. In particular, a Veeco Nexus LDD Ion Beam Deposition Tool was used for all depositions. The exact deposition parameters were determined by DOE using as software JMP, release 5.0 1a, by SAS Institute Inc., SAS Campus Drive, Cary, N.C. 27513, U.S.A.

Table A shows general deposition parameters for the sputtering of the materials used according to the Examples and Comparative Examples:

TABLE A
Exemplary general deposition parameters

| | Ta | SiO₂ | Al₂O₃ | Ta₂O₅ | Cr₂O₃ |
|---|---|---|---|---|---|
| Deposition Source | | | | | |
| Gas flow [sccm] | 10 | 10 | 10 | 10 | 10 |
| Sputter Gas | Ar | Ar | Ar | Ar | Ar |
| Assist Source | | | | | |
| Sputter Gas | — | O₂ | O₂ | O₂ | O₂ |
| Other | | | | | |
| Target material | Ta | Si | Al | Ta | Cr |
| Deposition rate [Å/s] | 1.20 | 0.29 | 0.32 | 0.57 | 0.85 |
| Background pressure | <3 | <3 | <3 | <3 | <3 |
| [×10⁻⁸ Torr] | | | | | |
| Deposition pressure | ˜2 | ˜2 | ˜2 | ˜2 | ˜2 |
| [×10⁻⁴ Torr] | | | | | |

| | Refractive Index | Extinction Coefficient |
|---|---|---|
| Material | at 193 nm | at 193 nm |
| SiO₂ film | 1.626 | 0.006 |
| Al₂O₃ film | 1.892 | 0.023 |
| Ta film | 1.632 | 2.578 |
| Cr₂O₃ film | 2.030 | 1.504 |
| Ta₂O₅ film | 2.107 | 1.272 |
| Substrate | 1.561 | 0 |

Two layer phase shift systems as described in U.S. patent application Ser. No. 10/655,593 comprising Ta (20 nm) as the transmission control layer and SiO₂ as the phase shift control layer (106 nm) are sputtered on a quartz substrate using the sputtering parameters as described in Table A.

As the substrate in all Examples and Comparative Examples quartz substrates having a thickness of 6.35 mm are used, if not otherwise specified.

### Example and Comparative Example 1

### Substrate for Mask Blanks

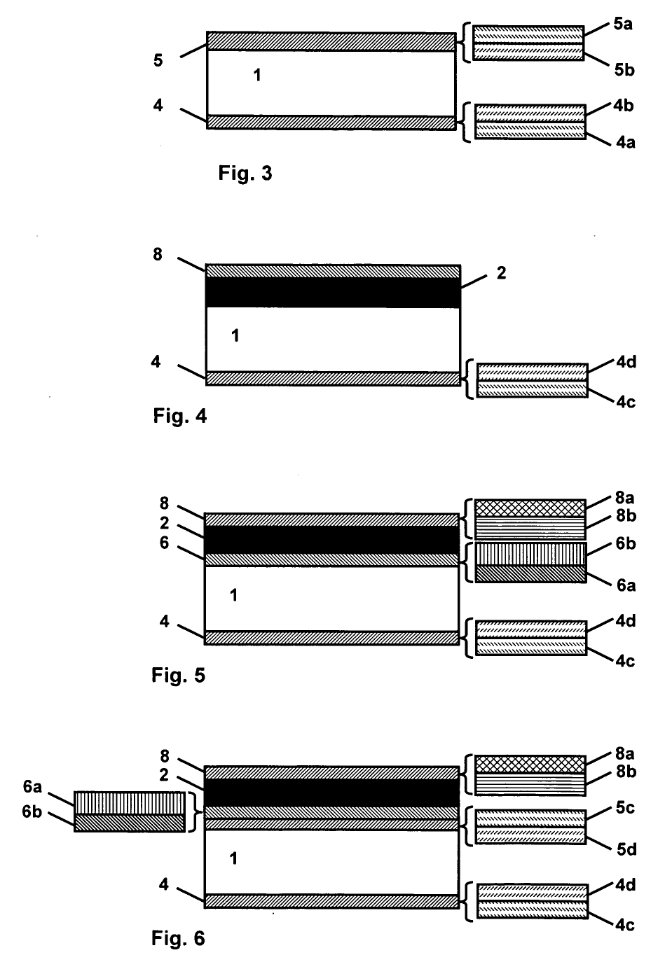

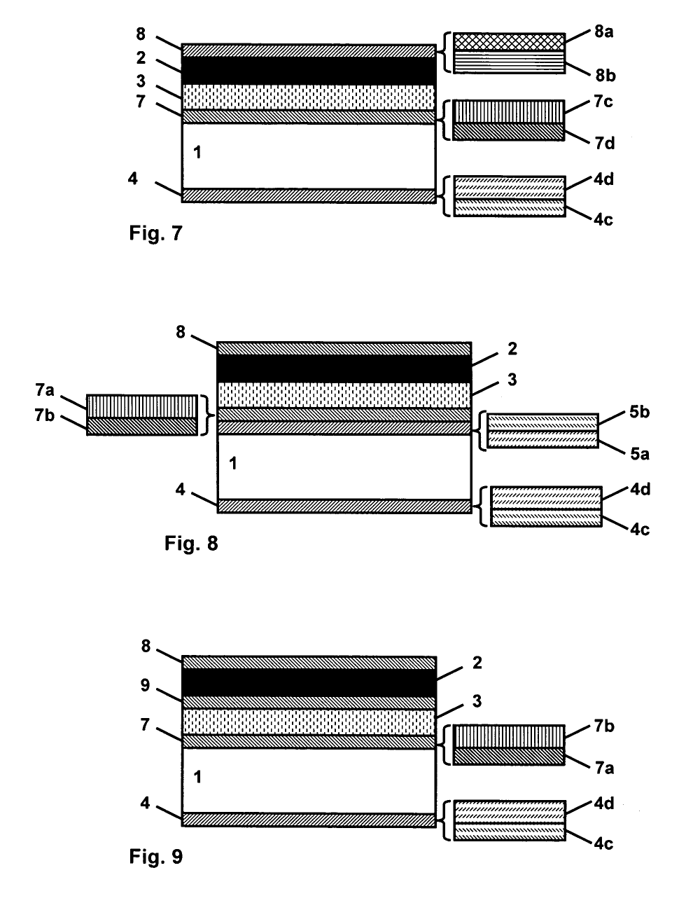

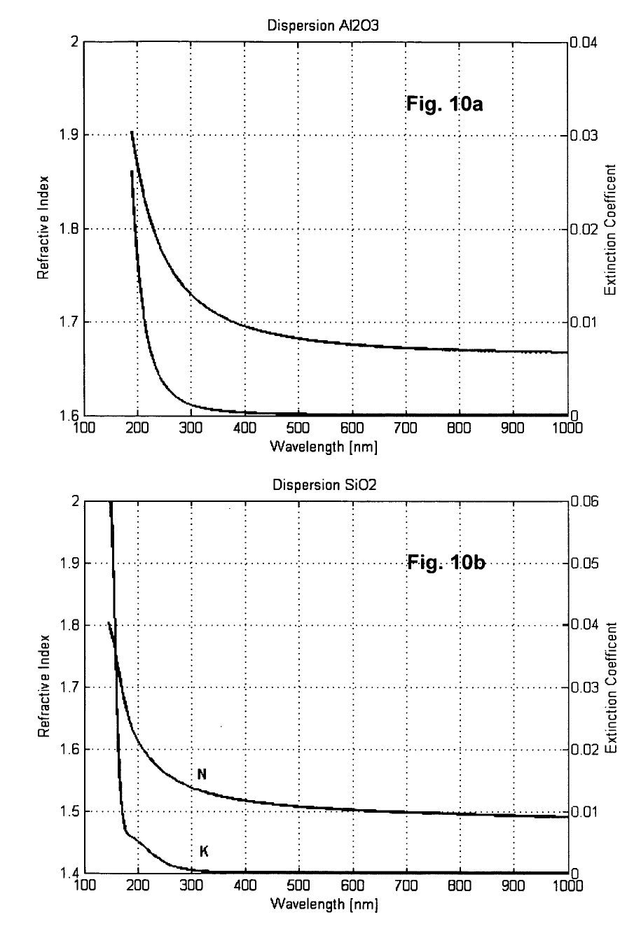

A substrate as schematically shown in FIG. 3 is prepared. On the backside of a substrate (1) a layer of Al₂O₃ (4b) and a layer of SiO₂ (4a) are sputtered, resulting in two layer antireflection layer (4). Then, the same two layer antireflection layer (5) (Al₂O₃ (5b); SiO₂ (5a)) is sputtered on the front side of substrate (1) to receive a substrate according to FIG. 3 having a two layer antireflection (AR) layer (coating) on both the front side and the backside of the substrate.

TABLE 1

| | Example 1 | | Comp. Example 1 | |
|---|---|---|---|---|
| | | Layer thick- | | Layer thick- |
| | Material | ness/nm | Material | ness |
| AR backside substrate | Al₂O₃ | 25.3 | — | — |
| AR backside substrate | SiO₂ | 29.3 | — | — |
| AR frontside substrate | Al₂O₃ | 25.3 | — | — |
| AR frontside substrate | SiO₂ | 29.3 | — | — |

| | | |
|---|---|---|
| Surface reflection at | 0.59 | 4.84 |
| 193 nm/% | | |
| Transmission/% | 94.52 | 95.16 |
| Absorption/% | 4.89 | 0 |

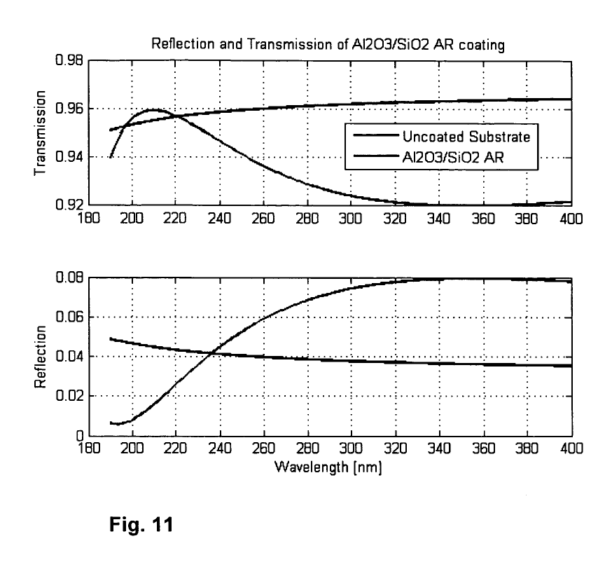

FIG. 11 further shows the performance of this substrate AR coating. The table lists the performance at the design wavelength of 193 nm.

Reflection at 193 nm is significantly lowered by a factor of 8 from 4.84% to 0.59%. There is a small loss in transmission of about 0.6% but this is tolerable. The film absorption of nearly 5% is therefore mainly taken from reflection and does not lower the transmission.

Since the top layer consists essentially of SiO₂ i.e. the same material as the substrate, the dry etch selectivity of e.g. chrome to substrate or SiO₂ layer remains the same.

FIG. 11 shows a comparison of the reflection of a AR coated substrate according to Example 1 (curved line) and an uncoated substrate (straight line, Comparative Example 1). The substrate AR coating reduces the reflection at 193 nm by a factor of 10 to below 0.5% whereas the transmission is only slightly lowered. The top layer of the two-layer AR is silicon dioxide, resulting in an unchanged chemical durability and dry etch performance.

### Example and Comparative Example 2

### Bilayer AR for Frontside of Absorbing Layer (Binary, PSM)

On a substrate, the following layers are coated using ion beam sputtering as described above:

| | | |
|---|---|---|
| absorbing layer (absorber) | 48 | nm |
| AR frontside absorbing layer (dielectric layer) | 10-16 | nm |
| AR frontside absorbing layer (semitransparent layer) | 6-15 | nm |

Table 2 lists the details of the sputtering experiments.

TABLE 2

| System | | | | Reflection [%] | | |
|---|---|---|---|---|---|---|
| | AR | AR | AR | 193 nm | 257 nm | 365 nm |
| Absorber | 1. layer | 2. layer | 3. layer | <10% | 6-20% | 6-20% |
| Cr | Ta₂O₅ | Al₂O₃ | none | Yes | Yes | Yes |
| | (14 nm) | (15 nm) | | | | |
| Cr | CrO | Al₂O₃ | none | Yes | Yes | Yes |
| | (16 nm) | (9 nm) | | | | |
| Cr | CrO | Al₂O₃ | CrO | Yes | Yes | No |
| | (2 nm) | (13 nm) | (2 nm) | | | |
| Ta | Ta₂O₅ | Al₂O₃ | none | Yes | Yes | Yes |
| | (14 nm) | (14 nm) | | | | |
| Ta | Ta₂O₅ | Al₂O₃ | none | Yes | Yes | Yes |
| | (14 nm) | (7 nm) | | | | |
| Ta | Ta₂O₅ | Al₂O₃ | Ta₂O₅ | Yes | Yes | Yes |
| | (2 nm) | (14 nm) | (7 nm) | | | |
| Ta | Al₂O₃ | Ta₂O₅ | none | Yes | Yes | Yes |
| | (14 nm) | (8 nm) | | | | |
| Ta | Al₂O₃ | CrO | none | Yes | Yes | Yes |
| | (10 nm) | (6.4 nm) | | | | |
| Ta | CrO | Al₂O₃ | none | Yes | Yes | Yes |
| | (10 nm) | (12 nm) | | | | |

All antireflective coatings of the absorber layer show a reflection at at least two inspection wavelengths within the specification, i.e. of less than 10%.

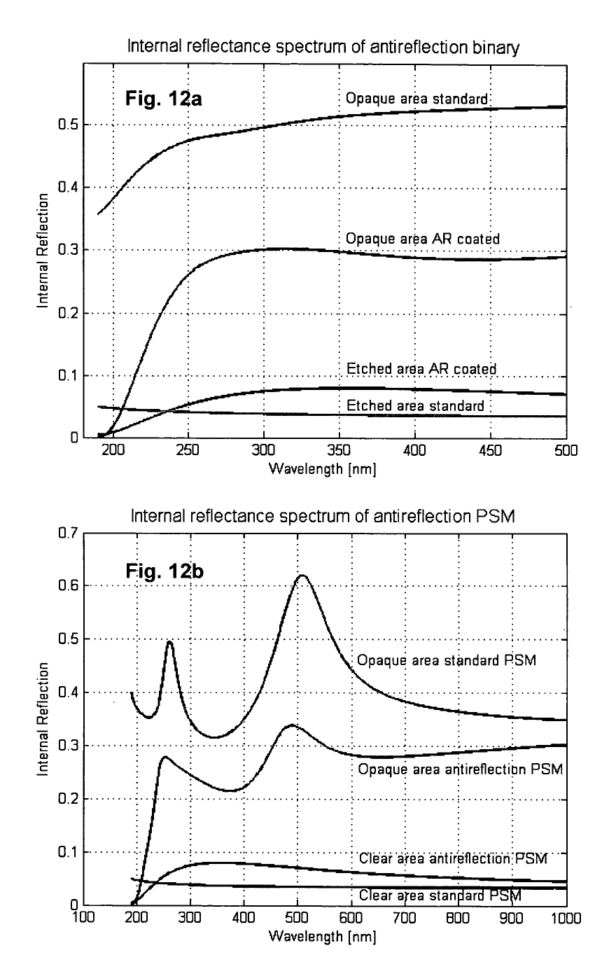

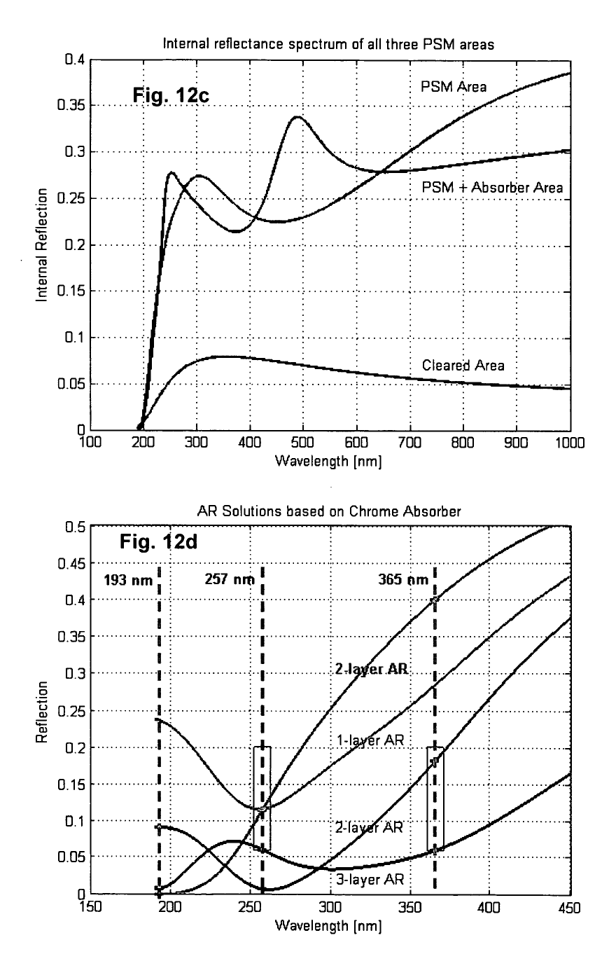

FIG. 12d shows a comparison of a standard Cr AR coating (“1-layer AR”, CrON, 12 nm) and two and three layered absorber AR coatings (“2-layer AR”).

Standard one-layer absorber AR coatings cannot lower reflection at 193 nm to below 20%. Two-layer AR coatings achieve low reflection at 193 nm lithography wavelength and can be further optimized to either 257 or 365 nm inspection wavelength requirements. Since 365 nm inspection will not be used for 65 nm node and beyond an optimal solution achieving zero reflection at 193 nm and 12% reflection at 257 nm inspection is available. Nevertheless if required three-layer AR coatings can be tuned to the requirements of all three wavelengths.

### Example 3 and Comparative Example 3

### Binary Mask Blank

On a substrate, the following layers were coated using ion beam sputtering as described above in the following order:

TABLE 3

| | | | Comp. | | |
|---|---|---|---|---|---|
| | Example 3 | | Example 3 | | |
| | | Layer | | Layer | |
| | | thickness/ | | thick- | |
| | Material | nm | Material | ness | Etching |
| AR frontside substrate | Al₂O₃ | 25.3 | — | — | — |
| AR frontside substrate | SiO₂ | 29.3 | — | — | — |
| AR backside absorbing | Cr | 4.0 | — | — | Chlorine |
| layer; semitransparent | | | | | etch |
| layer | | | | | |
| AR backside absorbing | Al₂O₃ | 18 | — | — | Chlorine |
| layer; dielectric | | | | | etch |
| layer | | | | | |
| absorbing layer | Cr | 48 | Cr | 48 | Chlorine |
| | | | | | etch |
| AR frontside | CrON | 12 | CrON | 12 | Chlorine |
| absorbing layer | | | | | etch |

| | Photoresist | Photoresist |
|---|---|---|
| Reflection etched | 0.4 | 4.8 |
| area at 193 nm/% | | |
| Reflection opaque | 0.1 | 36.3 |
| area at 193 nm/% | | |
| Transmission/% | 94.52 | 95.16 |
| Absorption/% | 4.89 | 0 |

The mask blanks according to Examples 3 and Comparative Example 3 patterned using standard techniques. A dry etching procedure is used, applying an etching agent as outlined in Table 3 above.

FIG. 12a shows the internal reflectance spectrum of a binary photomask according to Example 3 (“AR coated”) and Comparative Example 3 (“standard”). Backside reflection of a binary absorber at 193 nm without AR layer (Comparative Example 3) is near 40%. This high reflection is effectively suppressed by a two-layer AR coating (Example 3) to below 0.1%. Reflection is reduced in etched areas as well as in opaque areas. During structuring part of the AR stack is etched—enabled by an highly effective etch stop layer.

### Example 4 and Comparative Example 4

### Phase Shift Mask Blank

On a substrate, the layers as shown in Table 4 are coated using ion beam sputtering as described above. The phase shift layers according to Example 4 and Comparative Example 4 show a transmission of 6% and phase shift of 180° at 193 nm and are patterned using standard techniques. A dry etching procedure is used, applying an etching agent as outlined in Table 4.

TABLE 4

| | | | Comp. | | |
|---|---|---|---|---|---|
| | Example 4 | | Example 4 | | |
| | | Layer | | Layer | |
| | | thick- | | thick- | |
| | | ness/ | | ness/ | |
| | Material | nm | Material | nm | Etching |
| AR frontside substrate | Al₂O₃ | 25.3 | — | — | — |
| AR frontside substrate | SiO₂ | 29.3 | — | — | — |
| AR backside phase | Ta or | 3.5 | — | — | Chlorine |
| shift layer; semitransparent | Cr | | | | etch |
| layer | | | | | |
| AR backside phase | Al₂O₃ | 21.5 | — | — | Chlorine |
| shift layer; dielectric | | | | | etch |
| layer | | | | | |
| Phase shift layer | Ta | 17.5 | Ta | 17.5 | Chlorine |
| | | | | | etch |
| Phase shift layer | SiO₂ | 133.8 | SiO₂ | 133.8 | Fluorine |
| | | | | | etch |
| absorbing layer | Cr | 48 | Cr | 48 | Chlorine |
| | | | | | etch |
| AR frontside absorbing | CrON | 12 | CrON | 12 | Chlorine |
| layer | | | | | etch |

| | Photoresist | Photoresist |
|---|---|---|
| Reflection etched | 0.4 | 4.8 |
| area (surface substrate) | | |
| at 193 nm/% | | |
| Reflection etched | 0.1 | 36.3 |
| area (surface phase | | |
| shift layer) at 193 nm/% | | |
| Reflection opaque | | |
| area at 193 nm/% | 0.1 | 38.7 |
| Transmission/% | 94.52 | 95.16 |
| Absorption/% | 4.89 | 0 |

The reflection of opaque and etched areas of the mask blank and photomask according to Example 4 (schematically shown in FIG. 8) is substantially reduced compared to the mask blank according to Comparative Example 4.

FIG. 12b show a comparison of the internal reflection of photomasks according to Example 4 (“AR coated PSM”) and Comparative Example 4 (“standard PSM”). Backside reflection of a phase shift layer at 193 nm is also near 40%. Again this high reflection is effectively suppressed in both opaque (“opaque area” in FIG. 12b; “PSM+Absorber Area” in FIG. 12c) and etched areas to below 0.1%. The AR coating below the functional layer is also effective in regions where only the absorber is etched as shown in FIG. 12c (“PSM area”).

### Example 5 and Comparative Example 5

### EUV Mask Blank and Photomask

On a substrate of EUV grade ULE®, the following layers are coated using ion beam sputtering as described above:

TABLE 5

| | | | Comp. | | |
|---|---|---|---|---|---|
| | Example 5 | | Example 5 | | |
| | | Layer | | Layer | |
| | | thick- | | thick- | |
| | | ness/ | | ness/ | |
| | Material | nm | Material | nm | Etching |
| Backside coating | Cr | 60 | Cr | 60 | — |
| Reflective multilayer | Mo | 2.7 | Mo | 2.7 | |
| 40 pairs of Mo/Si | Si | 4.2 | Si | 4.2 | |
| Capping layer | Si | 11 | Si | 11 | — |
| Buffer layer | SiO₂ | 10 | SiO₂ | 10 | Fluorine |
| | | | | | etch |
| absorber layer | TaN | 55 | TaN | 55 | Cl₂ + O₂ |
| AR dielectric | Al₂O₃ | 11 | — | — | Cl₂ + O₂ |
| sublayer | | | | | |
| AR semitransparent | TaON | 6 | — | — | Cl₂ + O₂ |
| sublayer | | | | | |
| monolayer AR | — | — | TaON | 15 | |
| Overall layer thickness | | | | | |

| | Photoresist | Photoresist |
|---|---|---|
| Reflection at 365 nm/% | <10 | <10 |
| Reflection at 257 nm/% | <10 | 20 |

The mask blank according to Example 5 (schematically shown in FIG. 13) and Comparative Example 5 is patterned using standard techniques. A dry etching procedure is used, applying an etching agent as outlined above.

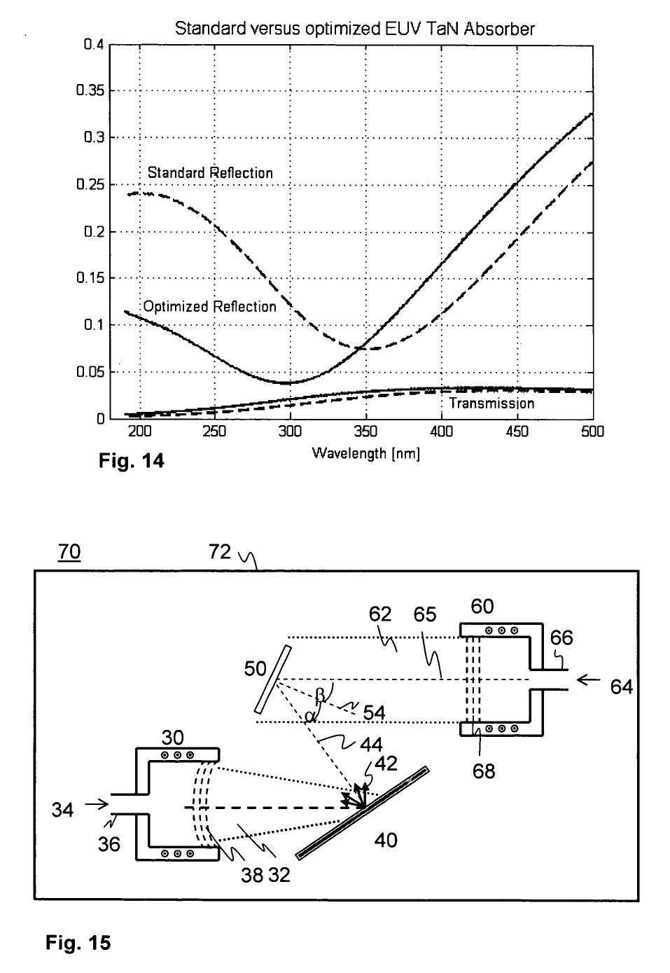

FIG. 14 shows a comparison of the reflectivity of the mask according to Example 5 and Comparative Example 5 at inspection wavelengths. The mask according to Comparative Example 5 exhibits a good reflectivity at an inspection wavelength of about 365 nm, however, reflectivity at inspection wavelength 257 nm is as high as 20%. The mask according to Example 5 exhibits a good reflectivity at both inspection wavelengths, i.e. a good reflectivity of less than 10% at 257 nm and 365 nm. Furthermore, the thickness of the layer system has increased only by 2 nm due to the two layer antireflection system.

The preceding examples can be repeated with similar success by substituting the generically or specifically described reactants and/or operating conditions of this invention for those used in the preceding examples.

From the foregoing description, one skilled in the art can easily ascertain the essential characteristics of this invention and, without departing from the spirit and scope thereof, can make various changes and modifications of the invention to adapt it to various usages and conditions.

In the Figures:
1 Substrate
2 Absorbing layer
3 Phase shift layer
4 AR coating on backside of substrate
5 AR coating on frontside of substrate
6 AR coating on backside of absorbing layer
7 AR coating on backside of phase shift layer
8 AR coating on frontside of absorbing layer
9 AR coating between absorbing layer and phase shift layer
10 internal reflection on backside surface of substrate
11 reflection on backside surface of absorbing layer
12 internal reflection on frontside of substrate
13 reflection of frontside of absorbing layer
. . . a semitransparent sublayer of AR layer
. . . b dielectric sublayer of AR layer
. . . c upper dielectric sublayer of substrate AR layer
. . . d lower dielectric sublayer of substrate AR layer
21 Substrate
22 Absorber layer
23 Multilayer stack
24 Capping layer
25 Buffer layer
26 first sublayer of AR layer
27 second sublayer of AR layer
28 Backside coating

We claim:

1. A mask blank comprising a substrate and a thin film system provided on the substrate, wherein said thin film system comprises at least three anti reflective layers wherein each of said antireflective layers comprises at least two sublayers of different composition,
said mask blank being able of producing a photomask at an exposure light having a wavelength of 300 nm or less.

2. A mask blank according to claim 1, wherein said mask blank is a mask blank is a binary mask blank and wherein the thin film system of the binary mask blank comprises an absorbing layer and anti reflective layers comprising at least two sublayers
at the front side of the absorbing layer,
at the backside of the absorbing layer
at the backside of the substrate.

3. A mask blank according to claim 1, wherein said mask blank is a mask blank is a phase shift mask blank and wherein the thin film system of the binary mask blank comprises an absorbing layer, a phase shift layer and anti reflective layers comprising at least two sublayers
at the front side of the absorbing layer,
at the backside of the phase shift layer
at the backside of the substrate.

4. The mask blank according to claim 3, additionally comprising an anti reflective layer comprising at least two layers at the front side of the substrate.

5. The mask blank according to claim 1, wherein said mask blank is a mask blank is a phase shift mask blank and wherein the thin film system of the binary mask blank comprises an absorbing layer, a phase shift layer and anti reflective layers comprising at least two sublayers
at the backside of the phase shift layer,
at the front side of the substrate,
at the back side of the substrate.

6. The mask blank according to claim 5, wherein said mask blank additionally comprises an anti reflective layer on the absorbing layer, said anti reflective layer consisting of one layer or comprising at least two sublayers.

7. The mask blank according to claim 1, wherein anti reflective layers comprising at least two sublayers and provided at the front and/or backside of the substrate are substantially not etched when the mask blank is transformed into a photomask.

8. The mask blank according to claim 7, wherein the upper sublayer of the anti reflective layer comprising at least two sublayers and provided on the front side and/or on the backside of the substrate comprise SiO₂ in an amount of at least 90 at. %.

9. The mask blank according to claim 1, wherein one, two or all of the anti reflective layers comprising at least two sublayers comprise a sublayer comprising oxides, oxy nitrides and/or nitrides of B, Al and/or Ga in an amount of at least 90 at. %.

10. The mask blank according to claim 1, wherein all sublayers of a specific anti reflective layer can be etched using the same etching agent.

11. The mask blank according to claim 1, said mask blank being able of producing a photo mask at an exposure light having a wavelength of 200 nm or less.

12. A mask blank comprising a substrate and a thin film system provided on the substrate, wherein said thin film system comprises at least one anti reflective layer having at least two sublayers wherein said anti reflective layer comprises a sublayer comprising oxides and/or nitrides of B, Al and/or Ga,
said mask blank being able of producing a photomask at an exposure light having a wavelength of 300 nm or less.

13. The mask blank according to claim 12, wherein the sublayer comprising oxides and/or nitrides of B, Al and/or Ga contains at least 90 at. % of oxides and/or nitrides of B, Al and/or Ga.

14. The mask blank according to claim 12, wherein said mask blank is a binary mask blank and comprises a substrate and an absorbing layer; wherein the anti reflective layer comprising a sublayer comprising oxides and/or nitrides of B, Al and/or Ga is provided at the front side of the absorbing layer, at a back side of the absorbing layer, at the front side of the substrate and/or at the backside of the substrate.

15. The mask blank according to claim 12, wherein said mask blank is a phase shift mask blank and comprises a substrate, an absorbing layer and a phase shift layer; wherein the anti reflective layer comprising a sublayer comprising oxides and/or nitrides of B, Al and/or Ga is provided at the front side of the absorbing layer, at the back side of the phase shift layer, at the front side of the substrate and/or at the backside of the substrate.

16. The mask blank according to claim 12, said mask blank being able of producing a photomask at an exposure light having a wavelength of 200 nm or less.

17. A substrate for a mask blank said mask blank being able of producing a photomask at an exposure light having a wavelength of 300 nm or less; wherein said substrate comprises an anti reflective layer on the front side and on the backside of the substrate, wherein said anti reflective layers each comprise at least two sublayers of different composition.

18. The substrate according to claim 17, wherein the sublayer of the anti reflective layer on the frontside of the substrate comprises oxides and/or nitrides of B, Al and/or Ga in an amount of at least 90 at. %.

19. The substrate according to claim 17, wherein the uppermost sublayer of the anti reflective layer comprises SiO₂ in an amount of at least 90 at. %.

20. The substrate according to claim 17, wherein the substrate is a calcium fluoride substrate, a quartz substrate or a fluorine-doped quartz substrate.

21. A substrate for a mask blank said mask blank being able of producing a photomask at an exposure light having a wavelength of 300 nm or less; wherein said substrate comprises an anti reflective layer on the front side and/or on the backside of the substrate; wherein said anti reflective layer comprises at least two sublayers of different composition; and wherein at least one sublayer comprises oxides and/or nitrides of B, Al and/or Ga.

22. A mask blank comprising a substrate according to claim 17 or claim 21, wherein said mask blank is a binary mask blank or a phase shift mask blank and is able of producing a photomask at an exposure light having a wavelength of 300 nm or less.

23. The mask blank according to claim 22, said mask blank being able of producing a photomask at an exposure light having a wavelength of 200 nm or less.

24. A mask blank comprising a substrate and a thin film system provided on the substrate, wherein said thin film system comprises an absorbing layer and an anti reflective layer on the absorbing layer, wherein said anti reflective layer on the absorbing layer comprises at least two sublayers of different composition, said mask blank being able of producing a photomask at an exposure light having a wavelength of 300 nm or less.

25. The mask blank according to claim 24, wherein said mask blank is a binary mask blank.

26. The mask blank according to claim 24, wherein said mask blank is a phase shift mask blank.

27. The mask blank according to claim 24, wherein the anti reflective layer comprises a dielectric sublayer and a further layer having a higher extinction coefficient than said dielectric layer.

28. The mask blank according to claim 24, wherein the dielectric sublayer comprises oxides and/or nitrides of Si, Ge, B, Al Ga and/or Hf in an amount of at least 90 at. %.

29. The mask blank according to claim 24, wherein the further layer comprises oxides, nitrides or oxy nitrides of a metal selected from the group consisting of Ti, Zr, V, Nb, Ta, Cr, Mo, W, Mn, Fe, Ru, Co, Ni, Cu, Zn, Sn or thereof mixtures.

30. A mask blank comprising a substrate and a thin film system provided on the substrate, wherein said thin film system comprises a functional layer and an anti reflective layer having at least two sublayers under said functional layer, wherein said anti reflective layer can be etched by the same etching agent as said functional layer, wherein the anti reflective layer comprises at least two sublayers of different composition, said mask blank being able of producing a photomask at an exposure light having a wavelength of 300 nm or less.

31. The mask blank according to claim 30 wherein the anti reflective layer comprises a dielectric sublayer and a semitransparent sublayer.

32. The mask blank according to claim 31, wherein the dielectric sublayer comprises oxides and/or nitrides of B, Al and/or Ga in an amount of at least 90 at. %.

33. The mask blank according to claim 31, wherein the semitransparent sublayer comprises a metal selected from the group consisting of Ti, Zr, Hf, V, Nb, Ta, Cr, Mo, W, Mn, Fe, Ru, Co, Ni, Cu, Zn, Sn or thereof mixtures.

34. The mask blank according to claim 30, additionally comprising an anti reflective layer on the substrate, wherein said anti reflective layer on the substrate is substantially not etched when the functional layer and the anti reflective layer under the functional layer are etched.

35. The mask blank according to claim 30, wherein the functional layer is a phase shift layer.

36. The mask blank according to claim 30, wherein the functional layer is an absorber layer.

37. An EUVL mask blank comprising a substrate and a thin film system provided on the substrate;
wherein said thin film system comprises
a reflective multilayer stack
an absorber layer
and wherein on the absorber layer an antireflection layer comprising at least two sublayers is provided, said sublayers comprising a dielectric layer and a semitransparent layer.

38. The mask blank according to claim 37, wherein said dielectric sublayer comprises oxides and/or nitrides of a metal selected from the group consisting of Si, Al, Ga, B, or mixtures thereof.

39. The mask blank according to claim 37, wherein the dielectric sublayer further comprises at most 5 at. % of metals selected from the group consisting of Ti, Zr, Hf, V, Nb, Ta, Cr, Mo, W, Mn, Fe, Ru, Co, Ni, Cu, Zn, Sn or mixtures thereof.

40. The mask blank according to claim 37, wherein the dielectric sublayer essentially consists of AlN or Al₂O₃.

41. The mask blank according to claim 37, wherein the semitransparent layer comprises a metal selected from the group consisting of Ti, Zr, Hf, V, Nb, Ta, Cr, Mo, W, Mn, Fe, Ru, Co, Ni, Cu, Zn, Sn or a mixture thereof.

42. The mask blank according to claim 41, wherein the semitransparent layer further comprises N, O, C, B, or mixtures thereof.

43. The mask blank according to claim 37, wherein the semitransparent layer essentially consists of TaON.

44. The mask blank according to claim 37, wherein the absorber layer essentially consists of TaN.

45. The mask blank according to claim 37, wherein the semitransparent layer has a thickness of from 2 to 10 nm.

46. The mask blank according to claim 37, wherein the dielectric layer has a thickness of from 2 to 15 nm.

47. The mask blank according to claim 37, wherein the antireflection layer comprising at least two sublayers has a thickness of from 10 to 20 nm.

48. The mask blank according to claim 37, wherein the thin film system further comprises a buffer layer, a capping layer and/or a backside coating.
